(19) United States
(12) Patent Application Publication
(10) Pub. No.: US 2025/0087653 A1
(43) Pub. Date: Mar. 13, 2025

(54) PACKAGED FLIP CHIP INTEGRATED PASSIVE DEVICES

(71) Applicant: MACOM Technology Solutions Holdings, Inc., Lowell, MA (US)

(72) Inventors: Jeremy Fisher, Raleigh, NC (US); Marvin Marbell, Cary, NC (US); Haedong Jang, San Jose, CA (US)

(21) Appl. No.: 18/466,300

(22) Filed: Sep. 13, 2023

(51) Int. Cl. H01L 25/18; H01L 23/00; H01L 23/367

(52) U.S. Cl. CPC H01L 25/18; H01L 23/367; H01L 24/13; H01L 24/16; H01L 24/29; H01L 24/32; H01L 24/73; H01L 2224/13147; H01L 2224/16227; H01L 2224/29144; H01L 2224/32225; H01L 2224/73253

(57) ABSTRACT

A package including an IPD according to some embodiments includes a circuit board; and a flip chip (FC) IPD die including a substrate material and at least one capacitor or inductor, The FC IPD die is mounted so that the at least one capacitor or inductor face an upper surface of the circuit board. The package further includes a top-side cooling structure thermally connected to a first planar surface of the FC IPD die. The first planar surface of the FC IPD die includes the substrate material. The package further includes at least one first mechanical support thermally connecting the circuit board to a second planar surface of the FC IPD die. The second planar surface of the FC IPD includes the at least one capacitor or inductor.

### FIELD

The present disclosure is directed to packaged integrated passive devices (IPDS), including flip-chip (FC) IPD dies packaged with FC radio frequency (RF) transistor dies.

### BACKGROUND

RF power amplifiers are used in a variety of applications such as base stations for wireless communication systems, etc. The signals amplified by the RF power amplifiers often include signals that have a modulated carrier having frequencies in the megahertz (MHz) to gigahertz (GHz) range. The baseband signal that modulates the carrier is typically at a relatively lower frequency and, depending on the application, can be up to 300 MHz or higher. Many RF power amplifier designs utilize semiconductor switching devices as amplification devices. Examples of these switching devices include power transistor devices, such as MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally-diffused metal-oxide semiconductor) transistors, etc.

RF amplifiers are typically formed as semiconductor integrated circuit chips. Most RF amplifiers are implemented in silicon or using wide bandgap semiconductor materials (i.e., having a band-gap greater than 1.40 eV), such as silicon carbide (SiC) and Group III nitride materials. As used herein, the term “Group Ill nitride” refers to those semiconducting compounds formed between nitrogen and the elements in Group III of the periodic table, usually aluminum (Al), gallium (Ga), and/or indium (In). The term also refers to ternary and quaternary compounds, such as AlGaN and AlInGaN. These compounds have empirical formulas in which one mole of nitrogen is combined with a total of one mole of the Group III elements.

RF amplifiers often include matching circuits, such as impedance matching circuits, that are designed to improve the impedance match between the active transistor die (e.g., including MOSFETs, HEMTs, LDMOS, etc.) and transmission lines connected thereto for RF signals at the fundamental operating frequency, and harmonic termination circuits that are designed to at least partly terminate harmonic products that may be generated during device operation, such as second and third order harmonic products. The termination of the harmonic products also influences generation of intermodulation distortion products.

The RF amplifier transistor die(s) as well as the impedance matching and harmonic termination circuits may be enclosed in a device package. A die or chip may refer to a small block of semiconducting material or other substrate on which electronic circuit elements are fabricated. Integrated circuit packaging may refer to encapsulating one or more dies in a supporting case or package that protects the dies from physical damage and/or corrosion, and supports the electrical contacts for connection to external circuits. The input and output impedance matching circuits in an integrated circuit device package typically include LC networks that provide at least a portion of an impedance matching circuit that is configured to match the impedance of the active transistor die to a fixed value. Electrical leads may extend from the package to electrically connect the RF amplifier to external circuit elements such as input and output RF transmission lines and bias voltage sources.

Many functional blocks such as impedance matching circuits, harmonic filters, couplers, baluns, and power combiners/dividers can be realized by IPDs. IPDs include passive electrical components and are generally fabricated using standard wafer fabrication technologies such as thin film and photolithography processing, and located in a surface mount device (SMD). The SMD(s) may be included in a package with an active transistor die(s).

IPDs are often used in high power applications, and heat is often self-generated by such IPDs during operation. If the IPD becomes too hot, its performance (e.g., for input matching or output matching of a RF power transistor) may deteriorate and/or the IPD may be damaged. As such, IPDs are typically mounted in an SMD, and the SMD is typically mounted in a package with other components such as a RF power transistor(s). Such a package, however, may be insufficient to dissipate self-generated heat of the SMD.

### SUMMARY

A package including an IPD die according to some embodiments includes a circuit board, and a FC IPD die including a substrate material and at least one capacitor or inductor. The FC IPD die is mounted so that the at least one capacitor or inductor face an upper surface of the circuit board. The package further includes a top-side cooling structure thermally connected to a first planar surface of the FC IPD die. The first planar surface of the FC IPD die includes the substrate material. The package further includes at least one first mechanical package support thermally connecting the circuit board to a second planar surface of the FC IPD die. The second planar surface of the FC IPD includes the at least one capacitor or inductor.

In some embodiments, a first height includes a height of the FC IPD die, a height of at least one first mechanical support, and a height of a thermally conductive bonding material.

The first height can be between 50 microns and 500 microns.

The substrate material of the FC IPD die can include silicon carbide (SIC).

The substrate material of the FC IPD die can include gallium nitride (GaN).

The substrate material of the FC IPD die can include at least one silicon substrate.

The substrate material of the FC IPD die can at least partially fill a space between the at least one mechanical support and the top-side cooling structure.

The substrate material of the FC IPD die can extend across at least a major first surface of the FC IPD die.

The top-side cooling structure can be thermally connected to the FC IPD die either directly or through a thermally conductive bonding material.

The top-side cooling structure can include a planar portion that extends in parallel to the circuit board along a length of the first planar surface of the FC IPD die.

The package including an IPD die can further include a gold (Au) backside layer that at least partially fills a space between the first planar surface of the FC IPD die and a thermally conductive bonding material connecting the Au backside layer to the top-side cooling structure.

The at least one mechanical support can be a non-electrical component, and the at least one mechanical support can be bonded to an electrical node of the circuit board for heat transfer.

The at least one mechanical support can include at least one copper (Cu) pillar thermally connecting the FC IPD die and the circuit board.

The at least one mechanical support can include at least one solder ball or solder bump thermally connecting the FC IPD die and the circuit board.

A package according to some embodiments includes a circuit board; and a FC RF power die including one or more transistors on a first substrate material. The FC RF power die includes a gate terminal, a drain terminal, and a source terminal. The FC RF power die is mounted so that the gate terminal, the drain terminal, and the source terminal face an upper surface of the circuit board. The package further includes at least one second mechanical package support thermally connecting the circuit board to a second planar surface of the FC RF power die. The second planar surface of the FC RF power die includes the gate terminal, the drain terminal, and the source terminal. The package further includes a FC IPD die including a second substrate material and at least one capacitor or inductor and the FC IPD die mounted so that the at least one capacitor or inductor face the upper surface of the circuit board. The package further includes at least one first mechanical package support thermally connecting the upper surface of the circuit board to a second planar surface of the FC IPD die including the at least one capacitor or inductor. The package further includes a top-side cooling structure thermally connected to a first planar surface of the FC IPD die including the second substrate material and to a first planar surface of the FC RF power die including the first substrate material.

In some embodiments of a package, a first height includes a height of the FC IPD die, a height of the at least one first mechanical support, and a height of a thermally conductive bonding material. A second height includes a height of the FC RF power die, a height of the at least one second mechanical support, and a height of a thermally conductive bonding material. The first height is about equal to the second height.

The first height and second height, in some embodiments, are between 50 microns and 500 microns.

In some embodiments of a package, the second substrate material of the FC IPD die and the first substrate material of the transistor die include SiC.

In other embodiments of a package, the second substrate material of the FC IPD die and the first substrate material of the transistor die include GaN.

In still other embodiments of a package, the second substrate material of the FC IPD die and the first substrate material of the transistor die include at least one silicon substrate.

In some embodiments of a package, the second substrate material of the FC IPD die at least partially fills a space between the at least one mechanical support of the FC IPD die and the top-side cooling structure.

In other embodiments of a package, the second substrate material of the FC IPD die can extend across at least a major first surface of the FC IPD die.

In yet other embodiments of a package, the top-side cooling structure is thermally connected to the first planar surface of the FC RF power die either directly or through a thermally conductive bonding material.

In still other embodiments of a package, the top-side cooling structure includes a planar portion that extends in parallel to the circuit board along a length of the first planar surface of the FC IPD die and a length of the first planar surface of the FC RF power die.

Some embodiments of a package further include a Au backside layer that at least partially fills a space between the first planar surface of the FC IPD die and the top-side cooling structure.

Some other embodiments of a package further include a Au backside layer that at least partially fills a space between the first planar surface of the FC RF power die and a thermally conductive bonding material connecting the Au backside layer to the top-side cooling structure.

In yet other embodiments of a package, at least one mechanical support of the FC IPD die is a non-electrical component, and the at least one mechanical support of the FC IPD die is bonded to an electrical node of the circuit board for heat transfer.

In some embodiments of a package, at least one mechanical support of the FC IPD die includes at least one Cu pillar thermally connecting the FC IPD die and the circuit board.

In other embodiments of a package, at least one mechanical support of the FC IPD die includes at least one solder ball or solder bump thermally connecting the first planar surface of the FC IPD die and the upper surface of the circuit board.

Yet other embodiments of a package further include an overmold material extending from the circuit board to the top-side cooling structure and laterally across a region between the FC RF power die and FC IPD die.

Additional features, advantages, and aspects of the disclosure may be set forth or apparent from consideration of the following detailed description, drawings, and claims. Moreover, it is to be understood that both the foregoing summary of the disclosure and the following detailed description includes examples and are intended to provide further explanation without limiting the scope of the disclosure as claimed.

### BRIEF DESCRIPTION OF THE DRAWINGS

The accompanying drawings, which are included to provide a further understanding of the disclosure, are incorporated in, and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 is a cross-section view illustrating a conventional package that includes a FC transistor die and an SMD.

FIG. 2 is a cross-section view of a package according to embodiments of the present disclosure;

FIG. 3 is a cross-section view of a package according to other embodiments of the present disclosure.

FIG. 4 is a cross-section view of a package according to yet other embodiments of the present disclosure.

FIG. 5 is a cross-section view of a package according to other embodiments of the present disclosure.

FIG. 6 is a cross-section view of a package according to still yet other embodiments of the present disclosure.

FIG. 7 is a cross-section view of a package according to other embodiments of the present disclosure.

FIG. 8 is a cross-section view of a package according to still other embodiments of the present disclosure;

FIG. 9 is a cross-section view of a package according to yet other embodiments of the present disclosure.

FIG. 10 is a cross-section view of a package according to other embodiments of the present disclosure.

FIG. 11 is a cross-section view of a package according to still other embodiments of the present disclosure.

### DETAILED DESCRIPTION

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a metal, a contact, or a substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a metal, a contact, or a substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the another element or intervening elements may be present. In contrast, when an element is referred to as being “directly connected” or “directly coupled” to another element, there are no intervening elements present.

Relative terms such as “below”, “above”, “upper”, “lower”, “horizontal”, “vertical”, “top”, “bottom”, or “middle” may be used herein to describe a relationship of one element, die, layer, or region to another element, die, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

IPDs include passive components, such as capacitors and/or inductors, that often are provided as commercial SMDs. SMDs may be included in a package with a RF transistor die (also referred to herein as an “active die”) as an input match or output match to transform impedances of the RF transistor die to a certain impedance or to an external system impedance. In other instances, an SMD may be included in package with an RF transistor die for direct current (DC) biasing or baseband termination.

RF transistor dies included in such a package often generate large amounts of heat. Additionally, when current of a RF transistor die (such as an RF power transistor die) flows through the passive components of an SMD, the parasitic resistance or equivalent series resistance (ESR) of the passive components often generate heat. In order to try to dissipate this heat, the RF transistor die and the SMD may be mounted on printed circuit board (PCB) in the package and the package may have a top side heat sink to try to dissipate the heat from the package.

A PCB can provide a simple and convenient way of interconnecting components such as the RF transistor die and the SMD, as the components can be soldered to pads on the PCB and RF transmission lines (e.g., microstrip transmission lines) may be formed in the printed circuit that electrically interconnect the components in a desired fashion. In some cases, the components can be interconnected solely through such RF transmission lines, eliminating the need for bond wire connections between components.

Circuit boards, such as PCBs, however, do not provide a good thermal dissipation path to dissipate heat generated in an SMD.

Semiconductor devices such as RF transistor dies may be mounted in a so-called “flip-chip” (FC) configuration where the semiconductor die is flipped over so that the “front” side of the semiconductor die (i.e., the side of the die in which the active region that includes the unit cell transistors is formed) is attached to the mounting substrate, and the opposed “back” side” of the die is left exposed. If an RF transistor die is mounted in flip-chip configuration on a circuit board, then a heat sink may be attached to the exposed back side of the semiconductor die. As most Group III nitride based RF transistor die are formed on SiC substrates—which have a high thermal conductivity—such a heat sink configuration may be very effective at dissipating heat from the RF transistor die.

However, when a package includes an SMD, or a FC RF transistor die and a SMD, on a circuit board and a heat sink attached at the top of the package, the SMD is typically relatively thin and may be thinner than other circuit elements such as a FC RF transistor die. The heat sink is typically designed to have a large area in the length and width directions (which are perpendicular to the thickness direction). When the package includes an SMD and a FC RF transistor die, for example, the heat sink may either directly contact the RF transistor die or is attached to the RF transistor die through thermally conductive materials, such gold (Au) and/or epoxy. As mentioned. the SMD, however, is typically relatively thin, and is thinner than the FC RF transistor die. Thus, an overmold of the package may fill a space between a top surface of the SMD and a lower surface of the heat sink. The overmold material between the SMD and the heat sink also does not provide a good thermal dissipation path to dissipate heat generated in the SMD.

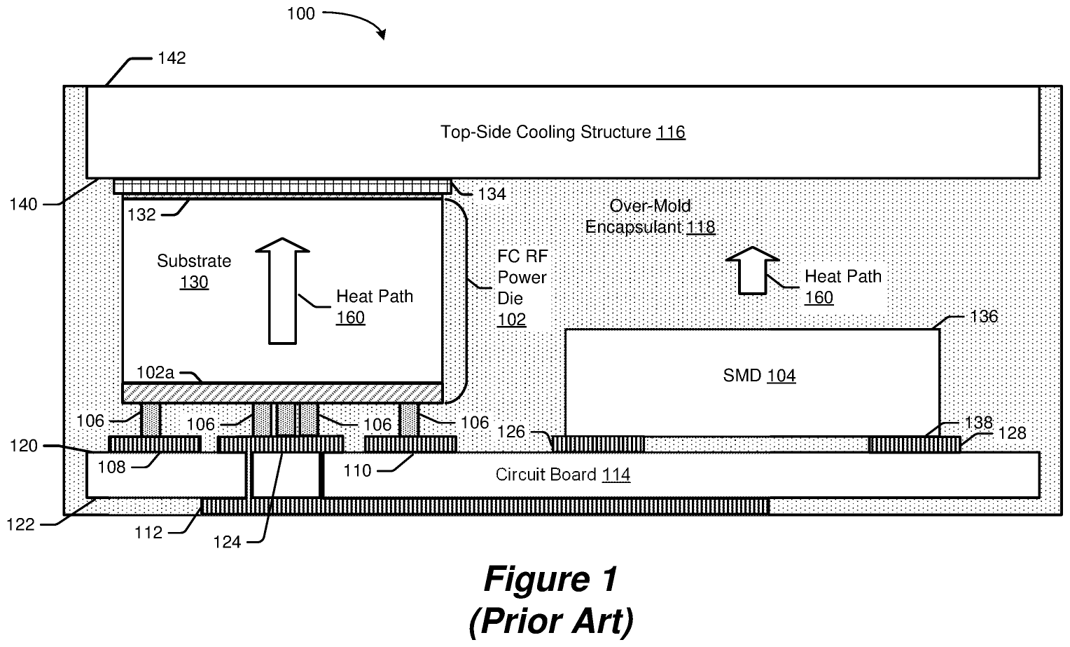

For example, FIG. 1 is a side view of an example of a conventional package 100 that includes RF power device 102 (e.g., an RF transistor die) in flip-chip configuration and a SMD 104 comprising passive components on a circuit board 114. The package 100 further includes a top side cooling structure sink 116 and an overmold encapsulation 118.

The circuit board 114 may include a RF-grade PCB that has an upper surface 120 and a lower surface 122. A plurality of metal pads 108, 124, 110, 126, 128 are provided on the upper surface 120 of circuit board 114. Pads 108, 124, 110 may include mounting pads for the FC RF power die 102, namely a gate pad 108, a source pad 124, and a drain pad 110. Electrical connections between the FC RF power die 102 and the circuit board 114 may be made through the pads 108, 124, 110. Electrical connections between the SMD 104 and the circuit board 114 may be made through the pads 126, 128.

The FC RF power die 102 may be mounted on the pads 108, 124, 110 using mechanical structures 106, which may be Cu pillars or solder balls/bumps, for example.

A bottom metal 112 may be formed on a portion of the bottom surface of the circuit board 114.

In addition, as discussed above, the RF power die 102 is flip-chip mounted on the circuit board 114 so that the front side of the RF power die 102 faces the circuit board 114. In the example in FIG. 1, the FC RF power die 102 is a transistor (such as a HEMT) formed on a substrate 130. The front side of the FC RF power die 102 is the surface where the active region of the FC RF power die 102 is formed, and the gate, drain, and source terminals are on the front side. The back side of the FC RF power die 102 is the surface that includes the substrate 130.

In FIG. 1, the gate terminal of FC RF power die 102 is connected via a mechanical support 106 to metal pad 108 on circuit board 114; the drain terminal is connected via a mechanical support to metal pad 110 on circuit board 114; and the source terminal is connected via three mechanical supports 106 to metal pad 124.

The backside of the FC RF power die 102 in this example includes a backside metal 132 (e.g., Au) on the substrate 130. Further, in this example, an epoxy material 134 is on the backside metal 132 and is attached to the top side cooling heat sink 116. The top surface 142 of top side cooling structure 116 is exposed to transfer heat to outside or to contact to an external heat sink. The package 100 is overmolded using overmold material 118. The FC RF power die 102 thickness is designed to directly contact the bottom surface 140 of the top side cooling heat sink 116 and attached using epoxy material or Ag sintering 134. Heat from the FC RF power die 102 can be conducted in both directions through the circuit board 114 to the bottom and/or through the top side cooling structure 116.

The SMD 104 may be an IPD that includes passive components, such as capacitors and/or inductors. SMD 104 can include passive components for input match or output match to transform the FC RF power die 102 impedances to a certain impedance or system impedance which are external. Additionally or alternatively, SMD 104 can include components for DC biasing or baseband termination. Heat of such passive SMDs, generated from self-heating through parasitic resistance or ESR and the current flowing through SMD 104 may be transferred in both directions through the bottom circuit board 114 and/or through the overmold material 118 and the top side cooling structure 116.

A primary heat path 160 for the configuration of SMD 104, however, is through the overmold encapsulation 118 and the top side cooling structure 116.

SMD 104 includes pads 126, 128 that are used to connect the SMD 104 to the circuit board 114. The pads 126, 128 are used to pass current flowing through SMD 104 to/from RF transmission lines on the circuit board 114 and the SMD 104. The SMD 104 may, for example, be used to form matching circuits for the FC RF power die 102.

The top side cooling structure 116, in this example, is attached to the FC RF power die 102 through thermally conductive materials including epoxy material 134 and backside metal 132 on substrate 130. The SMD 104 is thinner than the FC RF power die 102. Thus, an overmold encapsulation 118 of the package 100 fills a space between a top surface 136 of the SMD 104 and a lower surface 140 of the top side cooling structure 116. The overmold encapsulation 118 between the top surface 136 of SMD 104 and the lower surface 140 of the top side cooling structure 116 does not provide a good thermal dissipation path to dissipate heat generated in the SMD 104.

As previously discussed, the self-generated heat of SMD 104 may be from self-heating through parasitic resistance or ESR and the current flowing through SMD 104. The self-generated heat of the SMD 104, however, may not be sufficiently dissipated through the heat path 160 due to the SMD 104 packaging and the overmold encapsulation 118 between the SMD 104 the top side cooling structure 116.

Pursuant to embodiments of the present disclosure, packages including IPD dies are provided that are flip-chip mounted on an upper surface of a circuit board. The IPD die may have a passive component(s), such as a metal-insulator-metal (MIM) capacitor, on the front side of the IPD die, allowing the IPD die to be electrically connected to the circuit board through direct soldered connections. A top side cooling structure may be mounted to contact the opposed back side of the IPD die, facilitating removal of heat from the IPD die. Moreover, mechanical support mounting elements, such as Cu pillars or solder bumps/balls, may be included between the front side of the IPD die and a metal pad(s) on an upper surface the circuit board. Such a configuration facilitates “matching” a height of the IPD to the height of other components that contact the top side cooling structure, such as the height of an RF transistor die. Thus, such a flip-chip configuration of the IPD allows a primary heat path from the IPD that is through the FC IPD die and the top side cooling structure.

In some embodiments, a package includes an IPD die. The package includes a circuit board, and a FC IPD die including a substrate material and at least one capacitor or inductor. The FC IPD die is mounted so that the at least one capacitor or inductor face an upper surface of the circuit board. The package further includes a top-side cooling structure thermally connected to a first planar surface of the FC IPD die. The first planar surface of the FC IPD die includes the substrate material. The package further includes at least one first mechanical package support thermally connecting the circuit board to a second planar surface of the FC IPD die. The second planar surface of the FC IPD includes the at least one capacitor or inductor.

In other embodiments, a package includes a circuit board; and a FC RF power die including one or more transistors on a first substrate material. The FC RF power die includes a gate terminal, a drain terminal, and a source terminal. The FC RF power die is mounted so that the gate terminal, the drain terminal, and the source terminal face an upper surface of the circuit board. The package further includes at least one second mechanical package support thermally connecting the circuit board to a second planar surface of the FC RF power die. The second planar surface of the FC RF power die includes the gate terminal, the drain terminal, and the source terminal. The package further includes a FC IPD die including a second substrate material and at least one capacitor or inductor and the FC IPD die mounted so that the at least one capacitor or inductor face the upper surface of the circuit board. The package further includes at least one first mechanical package support thermally connecting the upper surface of the circuit board to a second planar surface of the FC IPD die including the at least one capacitor or inductor. The package further includes a top-side cooling structure thermally connected to a first planar surface of the FC IPD die including the second substrate material and to a first planar surface of the FC RF power die including the first substrate material.

It will also be appreciated that while the teachings of the present disclosure may be particularly useful with respect to packaged FC IPD dies and FC RF transistor dies that are mounted on a circuit board and include a top side cooling structure, embodiments of the present disclosure are not so limited. For example, techniques disclosed herein may be used in packaging any FC IPD die including, for example, a FC IPD that includes passive components for biasing or baseband termination. Moreover, FC RF transistor dies in such a package may include various types of transistors, for example, RF power transistors.

Example embodiments of the present disclosure will now be discussed further in detail with reference to the Figures.

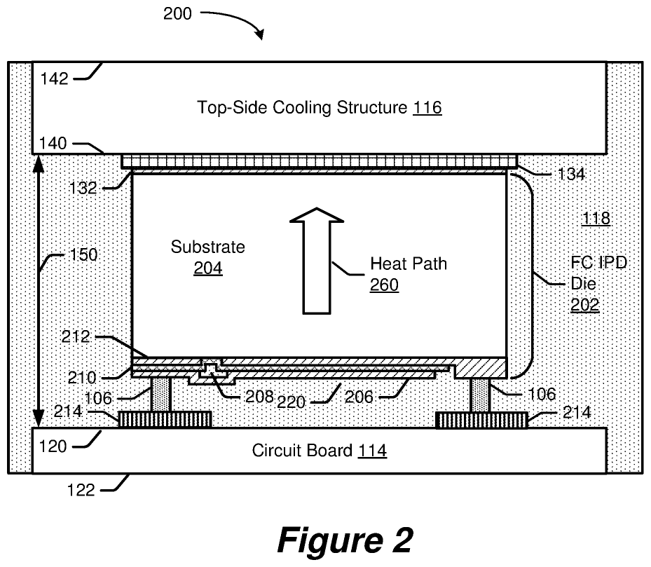

FIG. 2 is a schematic cross-sectional view of a package 200 that includes a FC IPD die 202. As shown, package 200 includes a circuit board 114, a FC IPD die 202, a plurality of mechanical supports 106, a top-side cooling structure 116, and an overmold encapsulation 118.

The FC IPD die 202 includes a substrate 204 and a metal-insulator-metal (MIM) capacitor 220. As shown, the FC IPD die 202 is mounted so that the MIM capacitor 220 faces an upper surface 120 of circuit board 114. The top-side cooling structure 116 is thermally connected to a first planar surface of the FC IPD die 202. The first planar surface of the FC IPD die 202 includes the substrate 204. In this example, two mechanical supports 106 are included that connect the circuit board 114 to a second planar surface of the FC IPD die 202. The second planar surface of the FC IPD die 202 includes the MIM capacitor 220 connected to metal pads 214. MIM capacitor 220 includes a top metal layer 206, a bottom metal layer 212, a dielectric material 210 between the top 206 and bottom metal layers 212, and an electrode 208.

The overmold encapsulation 118 may include an underfill material such as a capillary underfill material and may be injected in the space between the circuit board 114 and the top side cooling structure 116, and to also cover exposed portions of the circuit board 114, the side surfaces of the top side cooling structure 116, and the side surfaces of the FC IPD die 202.

In some embodiments, a first height includes a height of the FC IPD die, a height of at least one first mechanical support, and a height of a thermally conductive bonding material.

In FIG. 2, for example, a first height 150 includes a height of the FC IPD die 202, a height of the at least one first mechanical support 106, a height of metal pads 214, and a height of a thermally conductive bonding material 132, 134. The first height 150 is determined by a thickness of another component (not shown in FIG. 2) in the package 200, such as a thickness of a FC RF power die as discussed further herein. A height (e.g., thickness) and materials of the substrate 204 of the FC IPD die, metal pads 214, and a backside metal 132 (e.g., Au) and/or a thermally conductive epoxy material 134, respectively, may substantially match a thickness and materials of another component, such as a FC RF power die.

The package 200 of the configuration shown in FIG. 2 may have a number of advantages. By substantially matching the thickness of another component in package 200, such as a FC RF power die 202, thermal handling of the FC IPD die 202 may be improved by providing a low thermal resistance heat path 260 to the top side cooling structure 116. Additionally, such a configuration of the FC IPD die 202 may lower the cost and improve the thermal handling of an IPD because a via through substrate 204 is not needed and/or a minimal amount of backside metal 132 may be used for heat dissipation. Further, the configuration of the FC IPD die 202 can include a spiral inductor with a high-Q by moving the backside metal 132 farther away with the thicker substrate 204. Still further, based on this configuration of the FC IPD die 202 mechanical supports of the top side cooling structure 116 are not needed, which may simplify and decrease the cost of the top side cooling structure 116.

In some embodiments, the first height is between 50 microns and 500 microns.

The substrate 204 of FC IPD die 202 in some embodiments includes SiC.

In other embodiments, the substrate 204 of FC IPD die 202 includes GaN.

In yet other embodiments, the substrate 204 of FC IPD die 202 includes at least one Si substrate.

As shown in the example embodiment in FIG. 2, the substrate 204 material of the FC IPD die 202 at least partially fills a space between the at least one mechanical support 106 and the top-side cooling structure 116. Further, as shown in this example, the substrate 204 material of the FC IPD die 202 extends across at least a major first surface of the FC IPD die 202.

Further, as shown in the example embodiment in FIG. 2, the top-side cooling structure 116 is thermally connected to the FC IPD die 202 through a thermally conductive bonding material 134. In other embodiments, however, the top-side cooling structure 116 is thermally connected to the FC IPD die 202 either directly or through thermally conductive bonding material 134. This facilitates dissipating heat generated in the FC IPD die 202.

In some embodiments, as shown in FIG. 2, the top-side cooling structure 116 includes a planar portion that extends in parallel to the circuit board 114 along a length of the first planar surface of the FC IPD die 202, either directly or through the thermally conductive bonding material 134.

Further as shown in embodiment in FIG. 2, the package 200 can further include a backside metal layer 132 that at least partially fills a space between the first planar surface of the FC IPD die 202 and the thermally conductive bonding material 134 connecting the backside metal layer 132 to the top-side cooling structure 116. This facilitates dissipating heat generated in the FC IPD die 202, either directly or through the thermally conductive bonding material 134 and the backside metal layer 132.

In some embodiments, at least one mechanical support 116 is a non-electrical component, and is bonded to an electrical node of the circuit board 114 for heat transfer. Moreover, at least one mechanical support 116 can include at least one Cu pillar thermally connecting the FC IPD die 202 and the circuit board 114.

In other embodiments, however, at least one mechanical support 116 can include at least one solder ball or solder bump thermally connecting the FC IPD die 202 and the circuit board 114.

As described above, one complication with packages that include a FC RF power die is that the FC RF power die may have a height (or in other words, thickness) that is greater than a height of an IPD. Overmold encapsulation material may fill a space between an upper surface of the IPD die and a lower surface of a top side cooling structure at the top of the package. As a consequence, self-generated heat of the IPD die may not be sufficiently dissipated through this heat path due to at least the overmold encapsulation between the IPD die and the top side cooling structure. Pursuant to further embodiments of the present disclosure, packages are provided that have features that allow a height of the materials and at least some materials used in respective heat paths to be substantially matched for a FC RF power die and a FC IPD die.

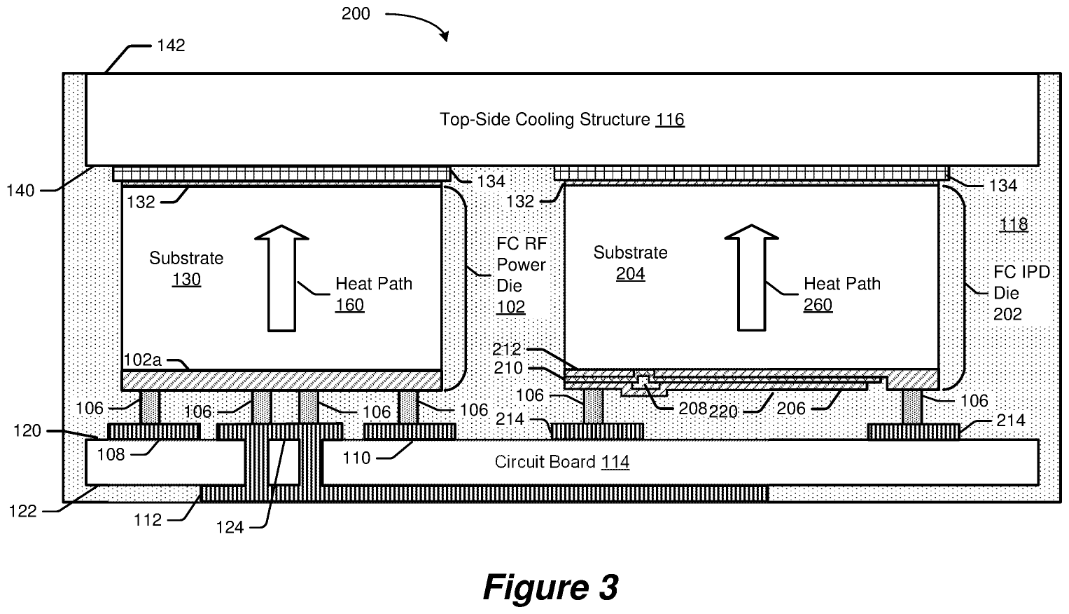

FIG. 3 is a schematic cross-sectional view of a package 200 that includes a FC IPD die 202. As shown, package 200 includes a circuit board 114, a FC RF power die 102, a FC IPD die 202, a plurality of mechanical supports 106, a top-side cooling structure 116, and an overmold encapsulation 118. The FC IPD die 202 may be identical to the corresponding components described above with reference to FIG. 2 and may be interconnected in the same way as described above. Thus, further detailed description that corresponds to FIG. 2 will be omitted.

The circuit board 114 may include a RF-grade PCB that has an upper surface 120 and a lower surface 122. A plurality of metal pads 108, 124, 110, 214 are provided on the upper surface 120 of circuit board 114. Pads 108, 124, 110 may include mounting pads for the FC RF power die 102, namely a gate pad 108, a source pad 124, and a drain pad 110. Electrical connections between the FC RF power die 102 and the circuit board 114 may be made through the pads 108, 124, 110. Electrical connections between the FC IPD die 202 and the circuit board 114 may be made through the pads 241.

The FC RF power die 102 may be mounted on the pads 108, 124, 110 using mechanical support 106, for example, Cu pillars.

A bottom metal 112 may be formed on a portion of the bottom surface of the circuit board 114.

In addition, as discussed above, the RF power die 102 is flip-chip mounted on the circuit board 114 so that the front side of the RF power die 102 faces the circuit board 114. In the example in FIG. 3, the FC RF power die 102 is a transistor (e.g., a HEMT) formed on substrate 130. The front side of the FC RF power die 102 is the surface where the active region of the FC RF power die 102 is formed, and the gate, drain, and source terminals are on the front side. The back side of the FC RF power die 102 is the surface that includes the substrate 130.

In FIG. 3, the gate terminal of RF power die 102 is connected via a mechanical structure 106 to top metal pad 108 on circuit board 114; the drain terminal is connected via a mechanical structure 106 to top metal pad 110 on circuit board 114; and the source terminal is connected via three mechanical structures 106 to a top metal pad 124.

The backside of the FC RF power die 102 in this example includes a backside metal 132 (e.g., Au) on the substrate 130. Further, in this example, a thermally conductive epoxy material 134 is on the backside metal 132 and is attached to a lower surface 140 of the top side cooling structure 116.

The top side cooling structure 116, in this example, is attached to the FC RF power die 102 through thermally conductive materials including epoxy material 134 and backside metal 132 on substrate 130.

In the example shown in FIG. 3, substrate 204 of the FC IPD die 202 is sized to contact to the top side cooling structure 116 via backside metal 132 and epoxy material 134. FC IPD die 202 is mounted on circuit board 114 using the same configuration as for the FC RF power die 102 using mechanical structures 106, such as Cu pillars or solder balls/bumps. For the opposing side, a same attach configuration as for the FC RF power die 102 also can be used to thermally connect the FC IPD die to top side cooling structure 116 via backside metal 132 and epoxy material 134.

As shown in FIG. 3, the FC IPD die 202 has a height that substantially matches the height of the flip-chip RF power die 102. Further the height of the respective back side metal 132 and the epoxy material 134 of the FC RF power die 102 and the FC IPD die 202 also substantially match. Additionally, in this example, a height of the mechanical structures 106 and the metal pads, 108, 124, 110, 214 of the FC RF power die 102 and the FC IPD die 202 also substantially match. Overmold encapsulation 118 of the package 200 fills: a space between the FC RF power die 102 and the FC IPD die 202; spaces between the sides of the package 200 and the sides of the flip-chip RF power die 102, the flip-chip IPD die 202a, the circuit board 114, and the top side cooling structure 116; and spaces between the front surfaces of the FC RF power die 102 and the FC IPD die 202 and the circuit board 114.

Thus, in FIG. 3, a height of the materials used in respective heat paths 160, 260 are substantially matched for the FC RF power die 102 and the FC IPD die 202. That is, the following thickness substantially match:
A thickness of metal pads 108, 124, 110 substantially match a thickness of metal pads 214;
A thickness of mechanical support structures 106 of the FC power die 102 and the FC IPD die 202 substantially match;
A thickness of active area 102a of FC power die 102 and MIM capacitor 220 of FC IPD die 202 substantially match;
A thickness of substrates 120 and 204 substantially match;
A thickness of backside metal 132 on the FC power die 102 and the FC IPD die 202 substantially match; and
A thickness of epoxy material 134 on the FC power die 102 and the FC IPD die 202 substantially match.

The package 200 of the configuration shown in FIG. 3 may have a number of advantages. The configuration may significantly improve the heat transfer of the FC IPD die 202 compared to the SMD 104 of FIG. 1 due to superior thermal conductivity of the substrate 204 (e.g., a SiC substrate) in heat path 260 in FIG. 3 compared to the overmold material 118 in heat path 160 in FIG. 1. Additionally, package 200 does not need a via (e.g., a Thru Substrate Via (TSV)) connection through the thermally conductive substrate 202. The configuration for heat path 260 may, therefore, dissipate more heat than such a via connection and may have a lower cost of manufacturing. Moreover, a minimal amount of backside metal 132 may be used to support Ag sintering attach. Further, the configuration of the FC IPD die 202 can include a spiral inductor with a high-Q by moving the backside metal 132 farther away with the thicker substrate 204. Still further, based on this configuration of the FC IPD die 202 and the FC RF power die 102, mechanical supports of the top side cooling structure 116 are not needed, which may simplify and decrease the cost of the top side cooling structure 116.

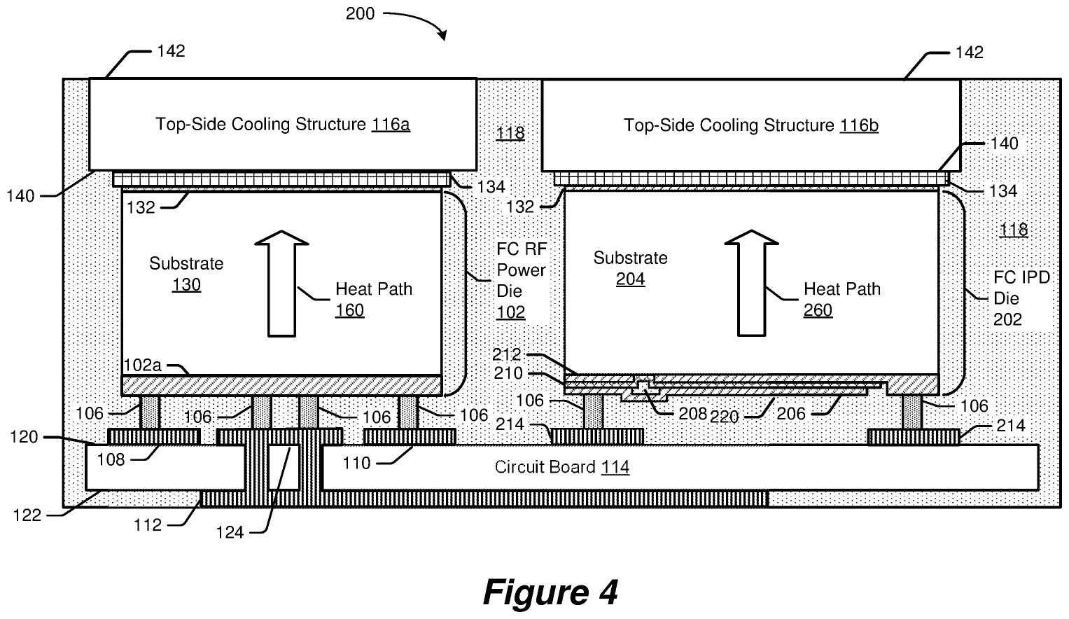

FIG. 4 is a schematic cross-sectional view of a package 200 that includes a FC IPD die 202 according to further embodiments of the present disclosure. The package 200 differs from previous embodiments in that it uses two separate top-side cooling structures 116a, 116b. Top-side cooling structure 116a is on FC RF power die 102; and top-side cooling structure 116b is on FC IPD die 202. The FC IPD die 202 and FC RF power die 102 may be identical to the corresponding components described above with reference to FIG. 3 and may be interconnected in the same way as described for FIG. 3 and, thus, further detailed description that corresponds to FIG. 3 will be omitted.

Thus, in FIG. 4, a height of the materials used in respective heat paths 160, 260 are substantially matched for the FC RF power die 102 and the FC IPD die 202. That is, the following thickness substantially match:
A thickness of metal pads 108, 124, 110 substantially match a thickness of metal pads 214;
A thickness of mechanical support structures 106 of the FC RF power die 102 and the FC IPD die 202 substantially match;
A thickness of active area 102a of FC RF power die 102 and MIM capacitor 220 of FC IPD die 202 substantially match;
A thickness of substrates 120 and 204 substantially match;
A thickness of backside metal 132 on the FC RF power die 102 and the FC IPD die 202 substantially match;
A thickness of epoxy material 134 on the FC RF power die 102 and the FC IPD die 202 substantially match; and
A thickness of the top-side cooling structures 116a, 116b substantially match.

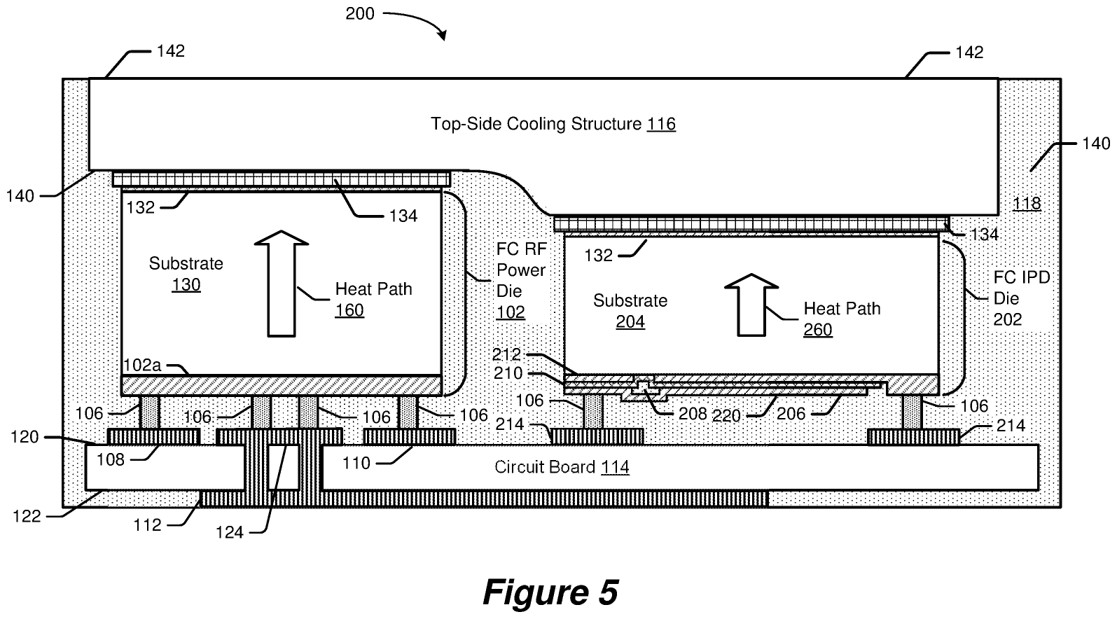

FIG. 5 is a schematic cross-sectional view of a package 200 that includes a FC IPD die 202 according to further embodiments of the present disclosure. The package 200 differs from previous embodiments in that it uses a shaped top-side cooling structure 116. Shaped top-side cooling structure 116 has a thinner height in the portion of top-side cooling structure 116 on FC RF power die 102; and shaped top-side cooling structure 116 has a thicker height in the portion of the top-side cooling structure 116 on FC IPD die 202. The FC IPD die 202 and FC RF power die 102 may be identical to the corresponding components described above with reference to FIG. 3 and may be interconnected in the same way as described for FIG. 3 and, thus, further detailed description that corresponds to FIG. 3 will be omitted.

Thus, in FIG. 5, an overall height of the materials used in respective heat paths 160, 260 are substantially matched for the FC RF power die 102 and the FC IPD die 202. That is, the following thickness substantially match:
A thickness of metal pads 108, 124, 110 substantially match a thickness of metal pads 214;
A thickness of mechanical support structures 106 of the FC RF power die 102 and the FC IPD die 202 substantially match;
A thickness of active area 102a of FC RF power die 102 and MIM capacitor 220 of FC IPD die 202 substantially match;
A thickness of backside metal 132 on the FC RF power die 102 and the FC IPD die 202 substantially match;
A thickness of epoxy material 134 on the FC RF power die 102 and the FC IPD die 202 substantially match.
The thickness of substrate 204 is thinner than the thickness of the substrate 130; and a thickness of a portion of the shaped top-side cooling structure 116 on FC IPD die 202 is thicker than the thickness of a portion of the shaped top-side cooling structure 112 on FC RF power die 102. However, the combined thickness of substrate 204 and the portion of shaped top-side cooling structure 116 on FC IPD die 202 substantially matches the combined thickness of substrate 130 and the portion of shaped top-side cooling structure 116 on FC RF power die 102.

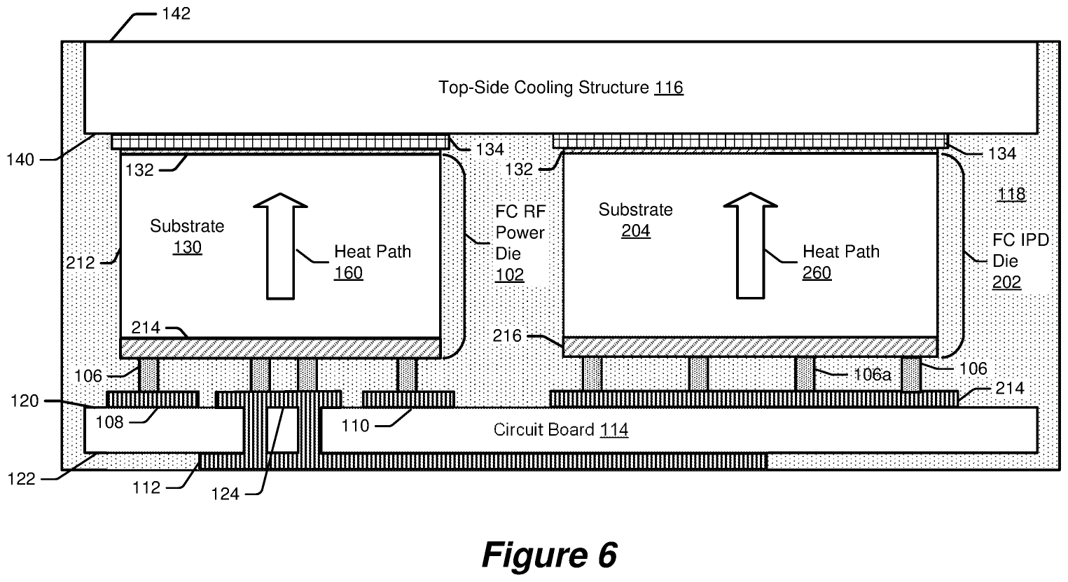

FIG. 6 is a schematic cross-sectional view of a package 200 that includes a flip-chip IPD die 202 according to further embodiments of the present disclosure. In FIG. 6, the passive component(s) 216 of FC IPD die 202 includes at least one additional mechanical structure 106a for connection to an electrical node on circuit board 114. The at least one additional mechanical structure 106a is a not electrically connected to circuit board 114; and is provided as a structure to provide heat transfer from a local hot spot on circuit board 114 of the electrical node. Moreover, FIG. 6 differs from previous embodiments in that passive component(s) 216 is not shown as a MIM capacitor, but rather is more generally shown and may be a capacitor(s) and/or inductor(s). Otherwise, the FC IPD die 202 and FC RF power die 102 may be identical to the corresponding components described above with reference to FIG. 3 and may be interconnected in the same way as described for FIG. 3 and, thus, further detailed description that corresponds to FIG. 3 will be omitted.

In FIG. 6, a height of the materials used in respective heat paths 160, 260 are substantially matched for the FC RF power die 102 and the FC IPD die 202. That is, the following thickness substantially match:
A thickness of metal pads 108, 124, 110 substantially match a thickness of metal pad 214;
A thickness of mechanical support structures 106 of the FC RF power die 102 and the FC IPD die 202 substantially match;
A thickness of active area 102a of FC RF power die 102 and passive component(s) 216 of FC IPD die 202 substantially match;
A thickness of substrates 120 and 204 substantially match;
A thickness of backside metal 132 on the FC RF power die 102 and the FC IPD die 202 substantially match; and
A thickness of epoxy material 134 on the FC power die 102 and the FC IPD die 202 substantially match.

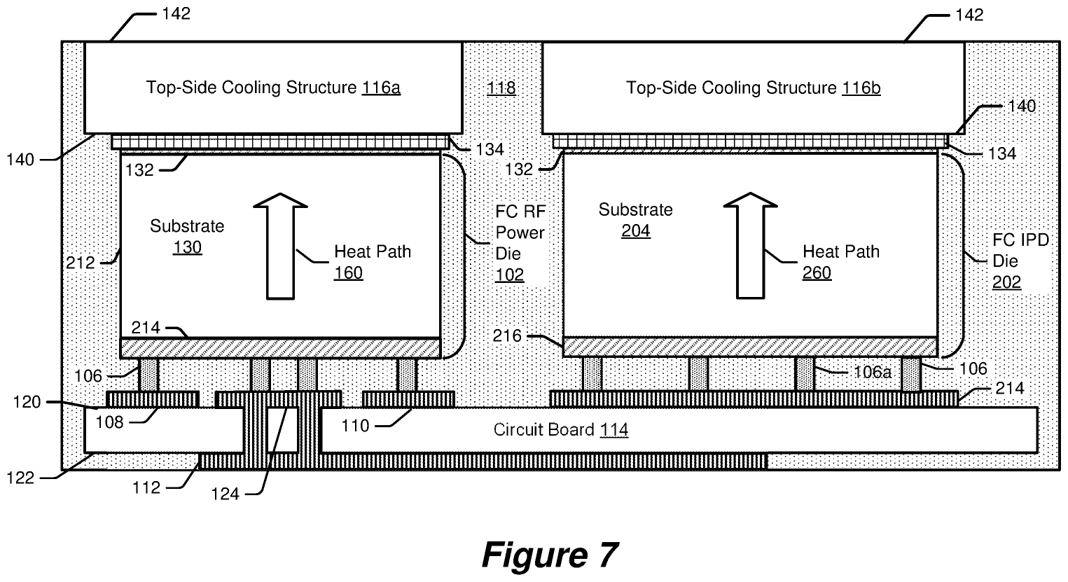

FIG. 7 is a schematic cross-sectional view of a package 200 that includes a FC IPD die 202 according to further embodiments of the present disclosure. The package 200 differs from the embodiment of FIG. 6 in that it uses two separate top-side cooling structures 116a, 116b. Top-side cooling structure 116a is on FC RF power die 102; and top-side cooling structure 116b is on FC IPD die 202. The FC IPD die 202 and FC RF power die 102 may be identical to the corresponding components described above with reference to FIGS. 3 and 6 and may be interconnected in the same way as described for FIGS. 3 and 6. Thus, further detailed description that corresponds to FIGS. 3 and 6 will be omitted.

Thus, in FIG. 7, a height of the materials used in respective heat paths 160, 260 are substantially matched for the FC RF power die 102 and the FC IPD die 202. That is, the following thickness substantially match:
A thickness of metal pads 108, 124, 110 substantially match a thickness of metal pad 214;
A thickness of mechanical support structures 106 of the FC RF power die 102 and the FC IPD die 202 substantially match;
A thickness of active area 102a of FC RF power die 102 and passive component(s) 216 of FC IPD die 202 substantially match;
A thickness of substrates 120 and 204 substantially match;
A thickness of backside metal 132 on the FC RF power die 102 and the FC IPD die 202 substantially match;
A thickness of epoxy material 134 on the FC RF power die 102 and the FC IPD die 202 substantially match; and
A thickness of the top-side cooling structures 116a, 116b substantially match.

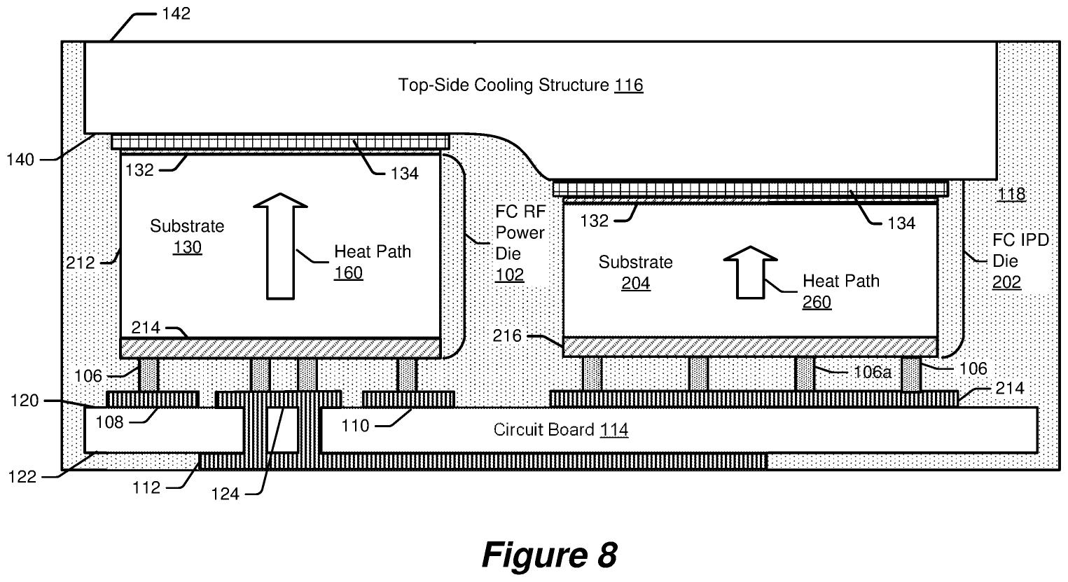

FIG. 8 is a schematic cross-sectional view of a package 200 that includes a FC IPD die 202 according to further embodiments of the present disclosure. The package 200 differs from the embodiment of FIG. 6 in that it uses a shaped top-side cooling structure 116. Shaped top-side cooling structure 116 has a thinner height in the portion of top-side cooling structure 116 on FC RF power die 102; and shaped top-side cooling structure 116 has a thicker height in the portion of the top-side cooling structure 116 on FC IPD die 202. The FC IPD die 202 and FC RF power die 102 may be identical to the corresponding components described above with reference to FIGS. 3 and 6, and may be interconnected in the same way as described for FIGS. 3 and 6. Thus, further detailed description that corresponds to FIGS. 3 and 6 will be omitted.

Thus, in FIG. 8, an overall height of the materials used in respective heat paths 160, 260 are substantially matched for the FC RF power die 102 and the FC IPD die 202. That is, the following thickness substantially match:
A thickness of metal pads 108, 124, 110 substantially match a thickness of metal pad 214;
A thickness of mechanical support structures 106 of the FC RF power die 102 and the FC IPD die 202 substantially match;
A thickness of active area 102a of FC RF power die 102 and passive component(s) 216 of FC IPD die 202 substantially match;
A thickness of backside metal 132 on the FC RF power die 102 and the FC IPD die 202 substantially match;
A thickness of epoxy material 134 on the FC RF power die 102 and the FC IPD die 202 substantially match.
The thickness of substrate 204 is thinner than the thickness of the substrate 130; and a thickness of a portion of the shaped top-side cooling structure 116 on FC IPD die 202 is thicker than the thickness of a portion of the shaped top-side cooling structure 112 on FC RF power die 102. However, the combined thickness of substrate 204 and the portion of shaped top-side cooling structure 116 on FC IPD die 202 substantially matches the combined thickness of substrate 130 and the portion of shaped top-side cooling structure 116 on FC RF power die 102.

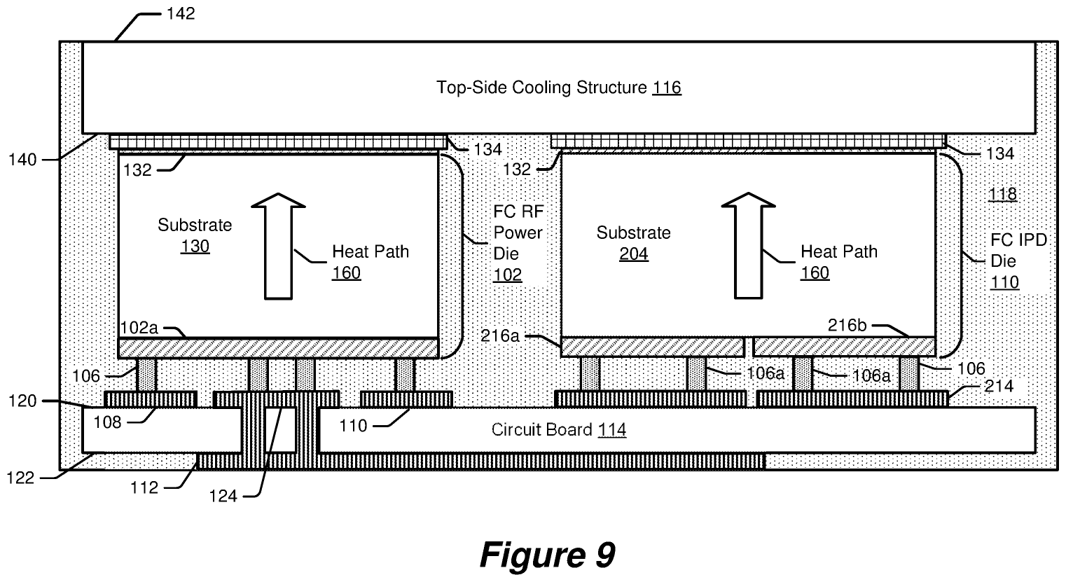

FIG. 9 is a schematic cross-sectional view of a package 200 that includes a flip-chip IPD 202 according to further embodiments of the present disclosure. In FIG. 9, the passive components 216 of FC IPD die 202 include two portions 216a, 216b. Passive components 216a, 216b are respectively connected to at least two additional mechanical structure 106a for connection to a plurality of electrical nodes on circuit board 114. The additional mechanical structures 106a are not electrically connected to circuit board 114; and are provided as structures to provide heat transfer from a plurality of local hot spots on circuit board 114 of the electrical nodes. Moreover, FIG. 9 differs from the embodiment of FIG. 3 in that passive components 216 are not shown as MIM capacitors, but rather are more generally shown and may be a capacitor(s) and/or inductor(s). Otherwise, the FC IPD die 202 and FC RF power die 102 may be identical to the corresponding components described above with reference to FIG. 3 and may be interconnected in the same way as described for FIG. 3. Thus, further detailed description that corresponds to FIG. 3 will be omitted.

In FIG. 9, a height of the materials used in respective heat paths 160, 260 are substantially matched for the FC RF power die 102 and the FC IPD die 202. That is, the following thickness substantially match:
A thickness of metal pads 108, 124, 110 substantially match a thickness of metal pads 214;
A thickness of mechanical support structures 106, 106a of the FC RF power die 102 and the FC IPD die 202 substantially match;
A thickness of active area 102a of FC RF power die 102 and passive components 216a, 216b of FC IPD die 202 substantially match;
A thickness of substrates 120 and 204 substantially match;
A thickness of backside metal 132 on the FC RF power die 102 and the FC IPD die 202 substantially match; and
a thickness of epoxy material 134 on the FC RF power die 102 and the FC IPD die 202 substantially match.

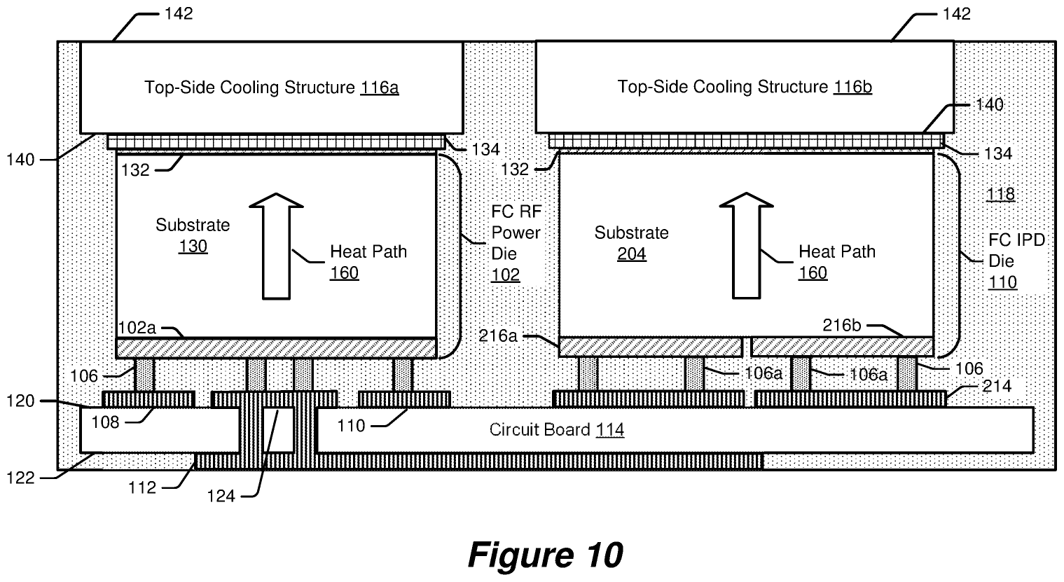

FIG. 10 is a schematic cross-sectional view of a package 200 that includes a FC IPD die 202 according to further embodiments of the present disclosure. The package 200 differs from the embodiment of FIG. 9 in that it uses two separate top-side cooling structures 116a, 116b. Top-side cooling structure 116a is on FC RF power die 102; and top-side cooling structure 116b is on FC IPD die 202. The FC IPD die 202 and FC RF power die 102 may be identical to the corresponding components described above with reference to FIGS. 3 and 9 and may be interconnected in the same way as described for FIGS. 3 and 9. Thus, further detailed description that corresponds to FIGS. 3 and 6 will be omitted.

Thus, in FIG. 10, a height of the materials used in respective heat paths 160, 260 are substantially matched for the FC RF power die 102 and the FC IPD die 202. That is, the following thickness substantially match:
A thickness of metal pads 108, 124, 110 substantially match a thickness of metal pads 214;
A thickness of mechanical support structures 106, 106a of the FC RF power die 102 and the FC IPD die 202 substantially match;
A thickness of active area 102a of FC RF power die 102 and passive components 216a, 216b of FC IPD die 202 substantially match;
A thickness of substrates 120 and 204 substantially match; A
thickness of backside metal 132 on the FC RF power die 102 and the FC IPD die 202 substantially match;
A thickness of epoxy material 134 on the FC RF power die 102 and the FC IPD die 202 substantially match; and
A thickness of the top-side cooling structures 116a, 116b substantially match.

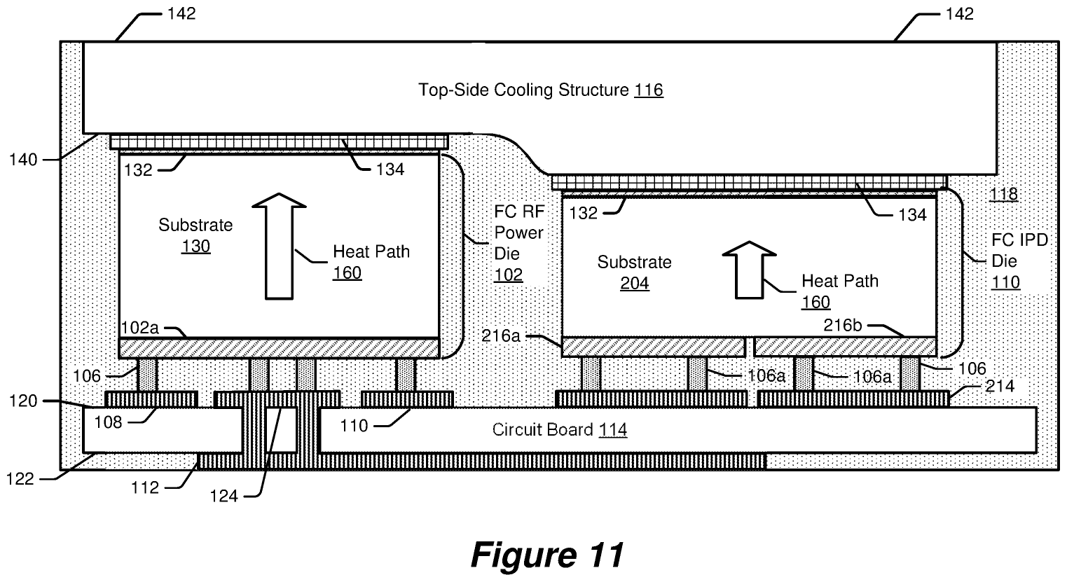

FIG. 11 is a schematic cross-sectional view of a package 200 that includes a FC IPD die 202 according to further embodiments of the present disclosure. The package 200 differs from the embodiment of FIG. 9 in that it uses a shaped top-side cooling structure 116. Shaped top-side cooling structure 116 has a thinner height in the portion of top-side cooling structure 116 on FC RF power die 102; and shaped top-side cooling structure 116 has a thicker height in the portion of the top-side cooling structure 116 on FC IPD die 202. The FC IPD die 202 and FC RF power die 102 may be identical to the corresponding components described above with reference to FIGS. 3 and 9, and may be interconnected in the same way as described for FIGS. 3 and 9. Thus, further detailed description that corresponds to FIGS. 3 and 9 will be omitted.

Thus, in FIG. 11, an overall height of the materials used in respective heat paths 160, 260 are substantially matched for the FC RF power die 102 and the FC IPD die 202. That is, the following thickness substantially match:
A thickness of metal pads 108, 124, 110 substantially match a thickness of metal pads 214;
A thickness of mechanical support structures 106, 106a of the FC RF power die 102 and the FC IPD die 202 substantially match;
A thickness of active area 102a of FC RF power die 102 and passive component(s) 216 of FC IPD die 202 substantially match;
A thickness of backside metal 132 on the FC RF power die 102 and the FC IPD die 202 substantially match;
A thickness of epoxy material 134 on the FC power die 102 and the FC IPD die 202 substantially match.
The thickness of substrate 204 is thinner than the thickness of the substrate 130; and a thickness of a portion of the shaped top-side cooling structure 116 on FC IPD die 202 is thicker than the thickness of a portion of the shaped top-side cooling structure 112 on FC RF power die 102. However, the combined thickness of substrate 204 and the portion of shaped top-side cooling structure 116 on FC IPD die 202 substantially matches the combined thickness of substrate 130 and the portion of shaped top-side cooling structure 116 on FC RF power die 102.

Each package of FIGS. 3-11 described above is illustrated as including one FC RF power die and one FC IPD die. It will be appreciated that the package according to embodiments of the present disclosure may include other numbers of FC RF power or transistor dies and/or other numbers of FC IPD dies.

Moreover, the packages shown in FIGS. 3, 4, 6, 7, 9, and 10 include a height of the materials used in respective heat paths 160, 260 that are substantially matched for the FC RF power die 102 and the FC IPD die 202; and the packages shown in FIGS. 5, 8, and 11 include a height of materials, other than the substrates, used in respective heat paths 160, 260 that are substantially matched for the FC RF power die 102 and the FC IPD die 202. The present disclosure, however, is not so limited. Rather, other embodiments include packages where the overall height (e.g., height 150 in FIG. 2) is substantially matched for the FC RF power die 102 and the FC IPD die 202, but heights of respective materials in the overall height may vary between for the FC RF power die 102 and the FC IPD die 202.

In some embodiments of a package, a first height includes a height of the FC IPD die, a height of the at least one first mechanical support, and a height of a thermally conductive bonding material. A second height includes a height of the FC RF power die, a height of the at least one second mechanical support, and a height of a thermally conductive bonding material. The first height is about equal to the second height.

The first height and second height, in some embodiments, are between 50 microns and 500 microns.

In some embodiments of a package, the second substrate material of the FC IPD die and the first substrate material of the transistor die include SiC.

In other embodiments of a package, the second substrate material of the FC IPD die and the first substrate material of the transistor die include GaN.

In still other embodiments of a package, the second substrate material of the FC IPD die and the first substrate material of the transistor die include at least one silicon substrate.

In some embodiments of a package, the second substrate material of the FC IPD die at least partially fills a space between the at least one mechanical support of the FC IPD die and the top-side cooling structure.

In other embodiments of a package, the second substrate material of the FC IPD die can extend across at least a major first surface of the FC IPD die.

In yet other embodiments of a package, the top-side cooling structure is thermally connected to the first planar surface of the FC RF power die either directly or through a thermally conductive bonding material.

In still other embodiments of a package, the top-side cooling structure includes a planar portion that extends in parallel to the circuit board along a length of the first planar surface of the FC IPD die and a length of the first planar surface of the FC RF power die.

Some embodiments of a package further include a Au backside layer that at least partially fills a space between the first planar surface of the FC IPD die and the top-side cooling structure.

Some other embodiments of a package further include a Au backside layer that at least partially fills a space between the first planar surface of the FC RF power die and a thermally conductive bonding material connecting the Au backside layer to the top-side cooling structure.

In yet other embodiments of a package, at least one mechanical support of the FC IPD die is a non-electrical component, and the at least one mechanical support of the FC IPD die is bonded to an electrical node of the circuit board for heat transfer.

In some embodiments of a package, at least one mechanical support of the FC IPD die includes at least one Cu pillar thermally connecting the FC IPD die and the circuit board.

In other embodiments of a package, at least one mechanical support of the FC IPD die includes at least one solder ball or solder bump thermally connecting the first planar surface of the FC IPD die and the upper surface of the circuit board.

Yet other embodiments of a package further include an overmold material extending from the circuit board to the top-side cooling structure and laterally across a region between the FC RF power die and FC IPD die.

While a package according to embodiments of the present disclosure illustrated above each use a conventional circuit board, such as a PCB, it will be appreciated that other types of circuit boards may be used such as, for example, a redistribution layer (RDL) laminate structure. An RDL laminate structure refers to a substrate that has conductive layer patterns and/or conductive vias for electrical and/or thermal interconnection. RDL laminate structures may be fabricated using semiconductor processing techniques by depositing conductive and insulating layers and/or patterns on a base material and by forming vias and copper routing patterns within the structure for transmitting signals through the RDL laminate structure. Other circuit boards that could be used in place of a PCB include specialized PCB (e.g., a metal core PCB) or a ceramic substrate that includes conductive vias and/or pads.

As discussed above, the packages according to embodiments of the present disclosure may include one or more Group III nitride based FC RF transistor dies.

The FC RF transistor dies according to embodiments of the present disclosure may be designed to operate in a wide variety of different frequency bands. In some embodiments, the FC RF transistor dies may be configured to operate at frequencies greater than 1 GHz. In other embodiments, these FC RF transistor dies may be configured to operate at frequencies greater than 2.5 GHZ. In still other embodiments, the FC RF transistor dies may be configured to operate at frequencies greater than 3.1 GHz. In yet additional embodiments, these FC RF transistor dies may be configured to operate at frequencies greater than 5 GHz. In some embodiments, these FC RF transistor dies may be configured to operate in at least one of the 2.5-2.7 GHZ, 3.4-4.2 GHZ, 5.1-5.8 GHZ, 12-18 GHz, 18-27 GHZ, 27-40 GHz or 40-75 GHz frequency bands or sub-portions thereof.

Although embodiments of the inventive concepts have been described in considerable detail with reference to certain configurations thereof, other versions are possible. The device can also have many different shapes. Accordingly, the spirit and scope of the invention should not be limited to the specific embodiments described above.

What is claimed is:

1. A package including an integrated passive device (IPD), the package comprising:
a circuit board;
a flip chip (FC) IPD die comprising a substrate material and at least one capacitor or inductor, the FC IPD die mounted so that the at least one capacitor or inductor face an upper surface of the circuit board;
a top-side cooling structure thermally connected to a first planar surface of the FC IPD die, the first planar surface of the FC IPD die comprising the substrate material; and
at least one first mechanical support thermally connecting the circuit board to a second planar surface of the FC IPD die, the second planar surface of the FC IPD comprising the at least one capacitor or inductor.

2. The package of claim 1, wherein a first height includes a height of the FC IPD die, a height of the at least one first mechanical support, and a height of a thermally conductive bonding material.

3. The package of claim 2, wherein the first height is between 50 microns and 500 microns.

4. The package of claim 1, wherein the substrate material of the FC IPD die comprises silicon carbide (SIC).

5. The package of claim 1, wherein the substrate material of the FC IPD die comprises gallium nitride (GaN).

6. The package of claim 1, wherein the substrate material of the FC IPD die comprises at least one silicon substrate.

7. The package of claim 1, wherein the substrate material of the FC IPD die at least partially fills a space between the at least one mechanical support and the top-side cooling structure.

8. The package of claim 7, wherein the substrate material of the FC IPD die extends across at least a major first surface of the FC IPD die.

9. The package of claim 1, wherein the top-side cooling structure is thermally connected to the FC IPD die either directly or through a thermally conductive bonding material.

10. The package of claim 1, wherein the top-side cooling structure includes a planar portion that extends in parallel to the circuit board along a length of the first planar surface of the FC IPD die.

11. The package of claim 1, further comprising a gold (Au) backside layer that at least partially fills a space between the first planar surface of the FC IPD die and a thermally conductive bonding material connecting the Au backside layer to the top-side cooling structure.

12. The package of claim 1, wherein the at least one mechanical support is a non-electrical component, and
the at least one mechanical support is bonded to an electrical node of the circuit board for heat transfer.

13. The package of claim 1, wherein the at least one mechanical support comprises at least one copper (Cu) pillar thermally connecting the FC IPD die and the circuit board.

14. The package of claim 1, wherein the at least one mechanical support comprises at least one solder ball or solder bump thermally connecting the FC IPD die and the circuit board.

15. A package comprising:
a circuit board;
a flip chip (FC) radio-frequency (RF) power die comprising one or more transistors on a first substrate material, wherein the FC RF power die includes a gate terminal, a drain terminal, and a source terminal, the FC RF power die mounted so that the gate terminal, the drain terminal, and the source terminal face an upper surface of the circuit board; and
at least one second mechanical support thermally connecting the circuit board to a second planar surface of the FC RF power die, the second planar surface of the FC RF power die comprising the gate terminal, the drain terminal, and the source terminal;
a FC IPD die comprising a second substrate material and at least one capacitor or inductor and the FC IPD die mounted so that the at least one capacitor or inductor face the upper surface of the circuit board;
at least one first mechanical support thermally connecting the upper surface of the circuit board to a second planar surface of the FC IPD die comprising the at least one capacitor or inductor; and
a top-side cooling structure thermally connected to a first planar surface of the FC IPD die comprising the second substrate material and to a first planar surface of the FC RF power die comprising the first substrate material.

16. The package of claim 15, wherein:
a first height includes a height of the FC IPD die, a height of the at least one first mechanical support, and a height of a thermally conductive bonding material;
a second height includes a height of the FC RF power die, a height of the at least one second mechanical support, and a height of a thermally conductive bonding material; and
the first height is about equal to the second height.

17. The package of claim 16, wherein the first height and second height are between 50 microns and 500 microns.

18. The package of claim 15, wherein the second substrate material of the FC IPD die and the first substrate material of the transistor die comprise silicon carbide (SIC).

19. The package of claim 15, wherein the second substrate material of the FC IPD die and the first substrate material of the transistor die comprise gallium nitride (GaN).

20. The package of claim 15, wherein the second substrate material of the FC IPD die and the first substrate material of the transistor die comprise at least one silicon substrate.

21. The package of claim 15, wherein the second substrate material of the FC IPD die at least partially fills a space between the at least one mechanical support of the FC IPD die and the top-side cooling structure.

22. The package of claim 21, wherein the second substrate material of the FC IPD die extends across at least a major first surface of the FC IPD die.

23. The package of claim 15, wherein the top-side cooling structure is thermally connected to the first planar surface of the FC IPD die either directly or through a thermally conductive bonding material.

24. The package of claim 15, wherein the top-side cooling structure is thermally connected to the first planar surface of the FC RF power die either directly or through a thermally conductive bonding material.

25. The package of claim 15, wherein the top-side cooling structure includes a planar portion that extends in parallel to the circuit board along a length of the first planar surface of the FC IPD die and a length of the first planar surface of the FC RF power die.

26. The package of claim 15, further comprising a gold (Au) backside layer that at least partially fills a space between the first planar surface of the FC IPD die and the top-side cooling structure.

27. The package of claim 15, further comprising a gold (Au) backside layer that at least partially fills a space between the first planar surface of the FC RF power die and a thermally conductive bonding material connecting the Au backside layer to the top-side cooling structure.

28. The package of claim 15, wherein the at least one mechanical support of the FC IPD die is a non-electrical component, and
the at least one mechanical support of the FC IPD die is bonded to an electrical node of the circuit board for heat transfer.

29. The package of claim 15, wherein the at least one mechanical support of the FC IPD die comprises at least one copper (Cu) pillar thermally connecting the FC IPD die and the circuit board.

30. The package of claim 15, wherein the at least one mechanical support of the FC IPD die comprises at least one solder ball or solder bump thermally connecting the first planar surface of the FC IPD die and the upper surface of the circuit board.

31. The package of claim 15, further comprising an overmold material extending from the circuit board to the top-side cooling structure and laterally across a region between the FC RF power die and FC IPD die.
